(19) United States
(12) Patent Application Publication
(10) Pub. No.: US 2015/0072583 A1
(43) Pub. Date: Mar. 12, 2015

(54) CURABLE RESIN COMPOSITION, CURED PRODUCT THEREOF, RESIN COMPOSITION FOR PRINTED CIRCUIT BOARD AND PRINTED CIRCUIT BOARD

(71) Applicant: DIC Corporation, Tokyo (JP)

(72) Inventors: Yoshiaki Murata, Ichihara-shi (JP); Takamitsu Nakamura, Ichihara-shi (JP); Koji Hayashi, Ichihara-shi (JP)

(21) Appl. No.: 14/389,024

(22) PCT Filed: Feb. 20, 2013
(86) PCT No.: PCT/JP2013/054156

§ 371 Date: Sep. 29, 2014

(30) Foreign Application Priority Data
Mar. 29, 2012 (JP) 2012-076626

(51) Int. Cl. C08L 63/04; H05K 1/03

(52) U.S. Cl. CPC C08L 63/04; H05K 1/0366; C08L 2201/08; C08L 2201/02; C08L 2203/20; H05K 2201/029; H05K 2201/05
USPC 442/141; 525/481; 524/364

(57) ABSTRACT

In the fields of printed wiring boards and circuit boards, a good glass cloth-penetrating property is exhibited and prepreg appearance is excellent. A cured product thereof exhibits good heat resistance. A phenolic resin is a phosphorus-atom-containing phenolic resin that has phosphorus-atom-containing structural portions (i) represented by structural formula (Y1) or (Y2) below and alkoxymethyl groups (ii) in an aromatic nucleus of a phenolic compound:

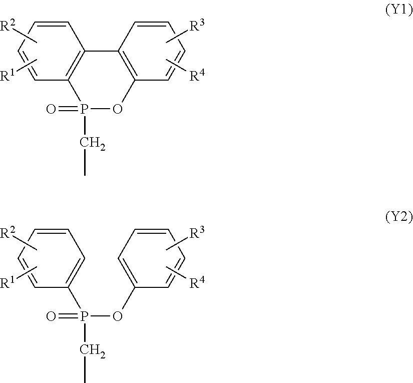

(In structural formulae (Y1) and (Y2), R¹ to R⁴ each independently represent a hydrogen atom or an alkyl group having 1 to 4 carbon atoms). A ratio of the number of the alkoxymethyl groups (ii) relative to the total number of the phosphorus-atom-containing structural portions (i) and the alkoxymethyl groups (ii) is 5 to 20%.

### TECHNICAL FIELD

The present invention relates to a curable resin composition that has a good glass-cloth penetrating property and good heat resistance as a cured product, a cured product thereof, a resin composition for a printed wiring board using the composition, and a printed wiring board.

### BACKGROUND ART

An epoxy resin composition that contains an epoxy resin and its curing agent as essential components has various desirable physical properties such as high heat resistance and moisture resistance and are widely used in electronic parts and electronic parts fields such as semiconductor sealing materials and printed circuit boards, conductive adhesives such as conductive paste, other adhesives, matrixes for composite materials, paints, photoresist materials, colorant materials, etc.

In recent years, further improvements of properties such as heat resistance, moisture resistance, and solder resistance have been particularly desirable in these usages and especially in advanced material usages. Vehicle-mounted electronic devices required to exhibit particularly high reliability require materials having higher heat resistance since these devices, which have been installed in cabins, are now increasingly installed in hotter engine rooms and since lead-free solder requires a higher reflow temperature.

When an epoxy resin composition is used as a printed wiring board material, a halogen-based flame retardant, for example, a bromine-based flame retardant, is used in combination with an antimony compound in order to impart flame retardancy. However, with an increasing concern over environment and safety in recent years, development of an environment-friendly, safety-oriented flame-retarding method that does not use a halogen-based flame retardant which may generate dioxins or an antimony compound suspected of being carcinogenic is highly anticipated. Moreover, in the field of printed wiring boards, use of halogen-based flame retardants has been a factor that impairs high-temperature exposure reliability and thus there is high expectation for halogen-free flame retardants.

PTL 1 described below discloses an epoxy resin composition that meets these requirements and has both flame retardancy and high heat resistance. According to this technology, a phosphorus-atom-containing phenolic resin is used as a curing agent for an epoxy resin and this phosphorus-atom-containing phenolic resin is obtained by causing a phenolic resin to react with a hydroxyl-group-containing phosphorus compound obtained by a reaction between 9,10-dihydro-9-oxa-10-phosphaphenanthrene-10-oxide (hereinafter, simply referred to as “HCA”) and formaldehyde or acetone. However, in the manufacturing process of this phosphorus-atom-containing phenolic resin, the reactivity of a polyfunctional phenol to HCA and aldehydes is low and thus reaction products between the HCA and the aldehydes remain as unreacted components in the resulting phenolic resin; hence, a cured product obtained therefrom has poor pyrolytic properties although it has high flame retardancy, and cannot withstand a thermal delamination test (hereinafter referred to as “T288 test”) that has served as an important criteria for lead-free solder mounting. Moreover, due to the low reactivity of the raw material described above, the type of the polyfunctional phenols that can be used is limited and the flexibility of designing phosphorus-atom-containing phenolic resins has been significantly limited.

PTL 2 discloses an intermediate phenolic compound for a phosphorus-atom-containing epoxy resin. This intermediate phenolic compound is obtained by causing a phenol to react with a reaction product between HCA and hydroxybenzaldehyde.

However, the reactivity between the phenol and the reaction product between HCA and hydroxybenzaldehyde is also low for this phenolic compound and the flexibility of the resin design is low. Moreover, the melting point of the final product phenolic compound is 200° C. or higher and thus the compound is difficult to produce industrially. The phenolic compound is also a crystalline substance and has low solubility in organic solvents, which makes handling difficult.

PTL 3 discloses a flame-retardant epoxy resin composition obtained by blending a curing agent for an epoxy resin and a phosphorus-modified epoxy resin as a base resin, the phosphorus-modified epoxy resin being obtained by causing HCA to react with a phenol novolac-type epoxy resin or a cresol novolac-type epoxy resin. However, according to the epoxy resin composition described in PTL 3, HCA is caused to react with epoxy groups, which should serve as crosslinking points otherwise, in order to introduce phosphorus atoms into the epoxy resin structure; thus, the crosslinking density is insufficient, the glass transition temperature of the cured product is decreased, and the cured product cannot withstand lead-free solder mounting.

PTL 4 discloses a technique of obtaining an HCA-containing phenolic resin. According to this technique, HCA is introduced into an aromatic nucleus of a phenolic resin by causing HCA to react with a phenolic resin that has a butoxymethyl group as a substituent on the aromatic nucleus and removing butanol. This resin has high phosphorus atom content and exhibits excellent flame retardancy; however, the viscosity of the resin itself is high. When the resin is used to make a prepreg for a printed wiring board or a circuit board, the resin exhibits a poor penetrating property to glass cloth, resulting in poor prepreg appearance and loss of homogeneity when formed into a laminate. Moreover, the resin cannot withstand thermal delamination resistance test (hereinafter simply referred to as “T288 test”).

As described above, various techniques that use HCA as a modifying agent for a phenolic resin or an epoxy resin are known. However, the heat resistance of a cured product is insufficient and the performance thereof does not pass the T288 test.

### CITATION LIST

### Patent Literature

PTL 1: Japanese Patent No. 3464783

PTL 2: Japanese Patent No. 3476780

PTL 3: Japanese Patent No. 3613724

### SUMMARY OF INVENTION

### Technical Problem

An object of the present invention is to provide a curable resin composition that exhibits a good glass-cloth penetrating property and offers good prepreg appearance in the fields of printed wiring boards and circuit boards and that exhibits good heat resistance when formed into a cured product, a cured product, a resin composition for a printed wiring board using the composition, and a printed wiring board.

### Solution to Problem

The inventors of the present invention have conducted extensive studies to resolve the technical problem and found that a phenolic resin that contains particular ratios of phosphorus-atom-containing structural portions and alkoxymethyl groups in a phenolic aromatic nucleus of a phenolic resin offers a good penetrating property when prepared into a composition and good prepreg appearance and that the cured product exhibits drastically improved heat resistance. Thus, the present invention has been made.

In other words, the present invention relates to a curable resin composition containing a phenolic resin (A) and an epoxy resin (B) as essential components, wherein the phenolic resin (A) is a phenolic resin that has phosphorus-atom-containing structural portions (i) represented by structural formula (Y1) or (Y2) below and alkoxymethyl groups (ii) in an aromatic nucleus of a phenolic compound:

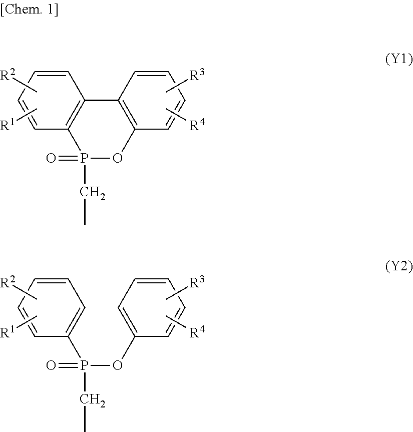

(In structural formulae (Y1) and (Y2), R¹ to R⁴ each independently represent a hydrogen atom or an alkyl group having 1 to 4 carbon atoms),
and a ratio of the number of the alkoxymethyl groups (ii) relative to the total number of the phosphorus-atom-containing structural portions (i) and the alkoxymethyl groups (ii) is 5 to 20%.

The present invention also relates to a cured product prepared by curing the curable resin composition described above.

The present invention also relates to a resin composition for a printed wiring board, comprising the phenolic resin (A), the epoxy resin (B), a curing accelerator (C), and an organic solvent (D).

The present invention also relates to a printed wiring board obtained by impregnating a glass substrate with a composition containing the phenolic resin (A), the epoxy resin (B), a curing accelerator (C), and an organic solvent (D), and then curing the composition.

The present invention also relates to a resin composition for a flexible wiring board, comprising a composition containing the phenolic resin (A), the epoxy resin (B), a curing accelerator (C), and an organic solvent (D).

The present invention also relates to a resin composition for a semiconductor sealing material, comprising the phenolic resin (A), the epoxy resin (B), a curing accelerator (C), and an inorganic filler.

The present invention also relates to a resin composition for an interlayer insulating material for a build-up substrate, comprising a composition containing the phenolic resin (A), the epoxy resin (B), a curing accelerator (C), and an organic solvent (D).

### Advantageous Effects of Invention

According to the present invention, a curable resin composition that exhibits a good glass-cloth penetrating property and offers good prepreg appearance in the fields of printed wiring boards and circuit boards and that exhibits good heat resistance when formed into a cured product can be provided. A cured product and a resin composition for a printed wiring board and a printed wiring board using the composition can also be provided.

### DESCRIPTION OF EMBODIMENTS

The present invention will now be described in detail. A phosphorus-atom-containing phenolic resin used as a phenolic resin (A) in the present invention is, as described above, a phenolic resin that has phosphorus-atom-containing structure portions (i) represented by structural formula (Y1) or (Y2) below and alkoxymethyl groups (ii) in an aromatic nucleus of a phenolic compound:

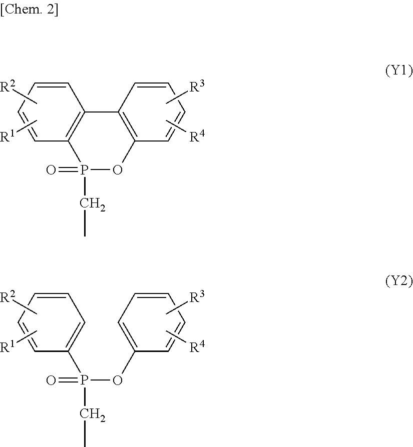

(In structural formulae (Y1) and (Y2), R¹ to R⁴ each independently represent a hydrogen atom or an alkyl group having 1 to 4 carbon atoms)
The ratio of the number of the alkoxymethyl groups (ii) relative to the total number of the phosphorus-atom-containing structure portions (i) and the alkoxymethyl groups (ii) is 5 to 20%.

As described above, according to the present invention, the aromatic nucleus in the phenolic resin contains not only the phosphorus-atom-containing structure portions (i) but also 5 to 20% of the alkoxymethyl groups (ii) relative to the total number of the phosphorus-atom-containing structure portions (i) and the alkoxymethyl groups (ii). Thus, the viscosity of the resin itself is low and the glass cloth penetrating property is enhanced.

The existence ratios of the phosphorus-atom-containing structure portions (i) and the alkoxymethyl groups (ii) can be derived from peak integral ratios of the methylene carbon atoms bonded to the phosphorus atom in structural formula (Y1) or (Y2) and terminal-methyl carbon atoms in the alkoxymethyl groups (ii) by ¹³C-NMR measurement. Identification of chemical shifts can be confirmed by using 1H-NMR analysis in combination if needed. In the case where there are two or more methylene groups per (ii) due to a branched structure of the alkoxymethyl groups (ii), the existence ratio of the methylene carbons constituting (ii) is first derived and then the result is divided by the number of methylene groups per (ii).

The alkoxy groups constituting the alkoxymethyl groups (ii) may be linear or branched alkyl. For example, the alkoxy groups are preferably alkoxy groups having 1 to 8 carbon atoms, e.g., a methoxy group, an ethoxy group, an n-propoxy group, an i-propoxy group, an n-butoxy group, a t-butoxy group, an n-octyloxy group, an s-octyloxy, a t-octyloxy group, and a 2-ethylhexyloxy group because the phenolic resin (A) exhibits low viscosity and excellent glass-cloth impregnating properties are exhibited. The alkoxy groups are preferably linear alkoxy groups and more preferably linear alkoxy groups having 1 to 4 carbon atoms since the phenolic resin (A) exhibits good curability and the cured product exhibits excellent heat resistance.

Examples of the phenolic compound include monovalent phenols such as phenol, cresol, xylenol, ethylphenol, isopropylphenol, t-butylphenol, octylphenol, nonylphenol, vinylphenol, isopropenylphenol, allylphenol, phenylphenol, benzylphenol, chlorophenol, bromophenol, and naphthol; divalent phenols such as catechol, resorcinol, hydroquinone, 1,5-dihydroxynaphthalene, 1,6-dihydroxynaphthalene, and 2,7-dihydroxynaphthalene; bisphenols such as bisphenol A, bisphenol F, bisphenol S, and a bisphenol having a structure obtained by connecting the monovalent phenols via a dimethylene ether bond (—CH₂—O—CH₂—); novolac-type phenolic resin such as phenol novolac resin, cresol novolac resin, bisphenol A novolac resin, bisphenol S novolac resin, α-naphthol novolac resin, β-naphthol novolac resin, dihydroxynaphthalene novolac resin, and other novolac resin represented by structural formula (Ph-1) below:

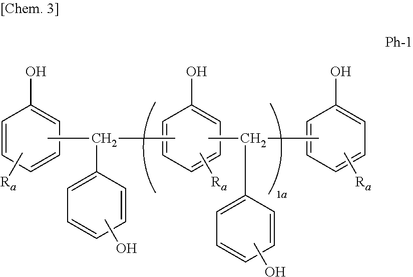

(In the formula, Ra represents a hydrogen atom or a hydrocarbon group having 1 to 6 carbon atoms and 1a represents the number of repeating units and is an integer in the range of 0 to 10);
phenolic resin having a molecular structure in which phenols are connected via an alicyclic hydrocarbon group selected from the group consisting of dicyclopentadiene, tetrahydroindene, 4-vinylcyclohexene, 5-vinylnorbon-2-ene, α-pinene, β-pinene, and limonene;
aralkyl-type phenolic resin represented by structural formula (Ph-2) below:

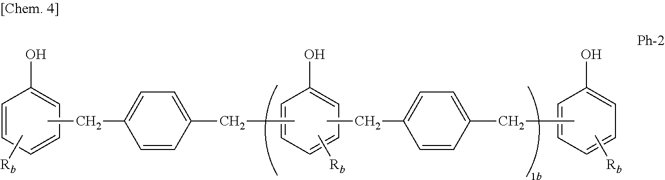

(In the formula, Rb represents a hydrogen atom or a hydrocarbon group having 1 to 6 carbon atoms and 1b represents the number of repeating units and is an integer in the range of 0 to 10);
aralkyl-type phenolic resin represented by structural formula (Ph-3) below:

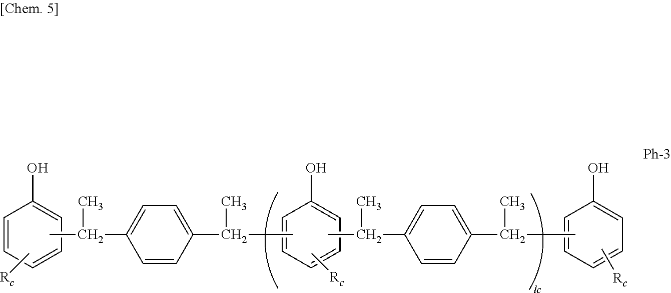

(In the formula, Rc represents a hydrogen atom or a hydrocarbon group having 1 to 6 carbon atoms and 1c represents the number of repeating units and is an integer in the range of 0 to 10);
aralkyl-type phenolic resin represented by structural formula (Ph-4) below:

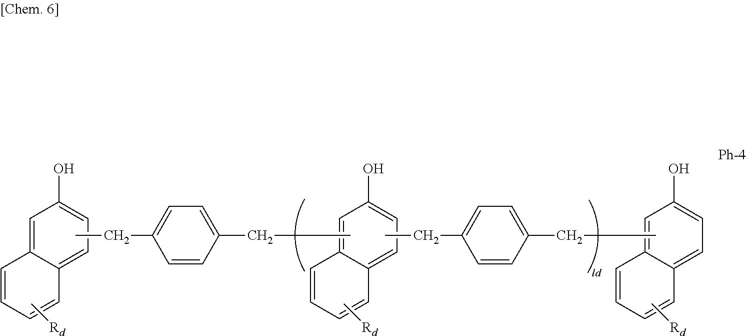

(In the formula, Rd represents a hydrogen atom or a hydrocarbon group having 1 to 6 carbon atoms and 1d represents the number of repeating units and is an integer in the range of 0 to 10);
aralkyl-type phenolic resin represented by structural formula (Ph-5) below:

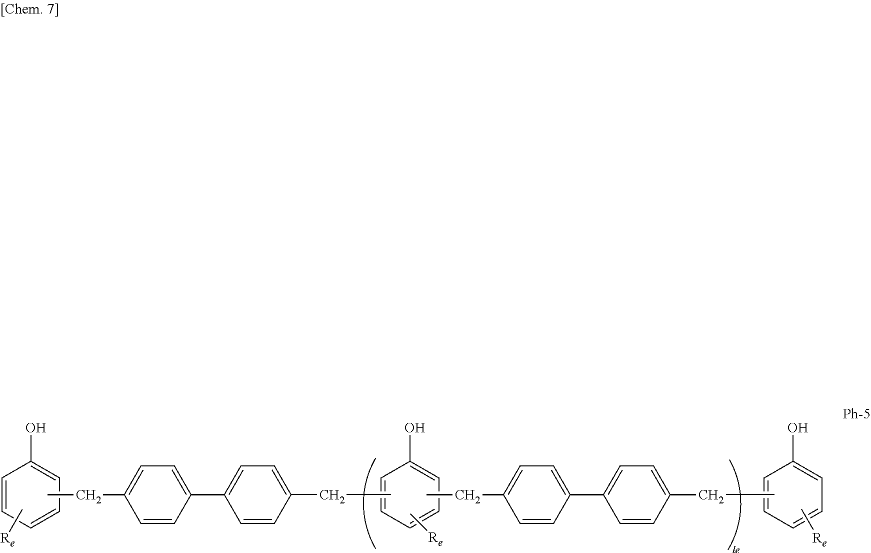

(In the formula, Re represents a hydrogen atom or a hydrocarbon group having 1 to 6 carbon atoms and 1e represents the number of repeating units and is an integer in the range of 0 to 10);
aralkyl-type phenolic resin represented by structural formula (Ph-6) below:

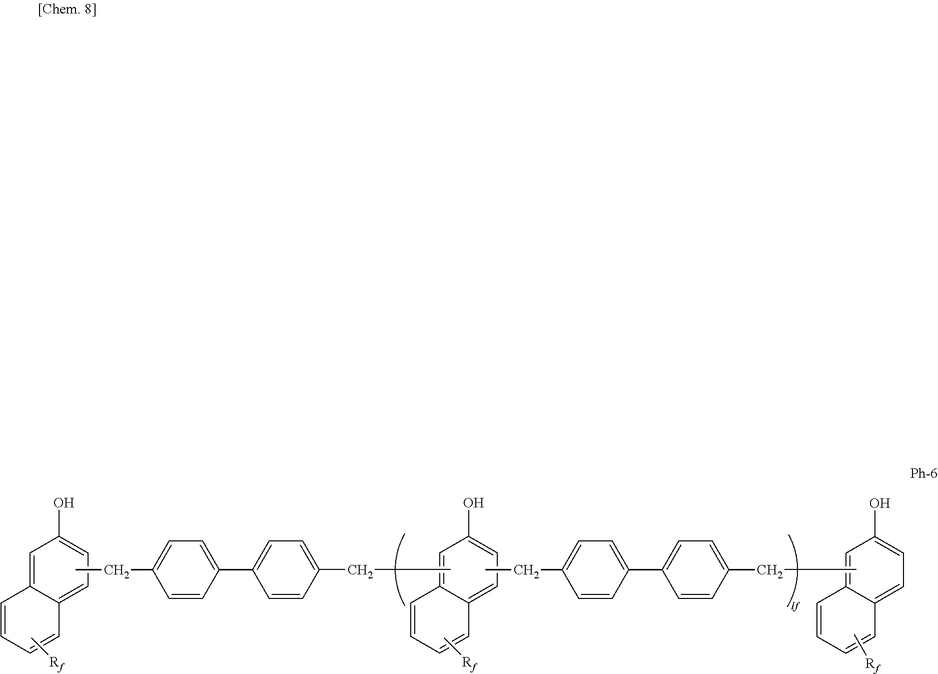

(In the formula, Re represents a hydrogen atom or a hydrocarbon group having 1 to 6 carbon atoms and if represents the number of repeating units and is an integer in the range of 0 to 10);
aralkyl-type phenolic resin such as a compound represented by structural formula (Ph-7) below:

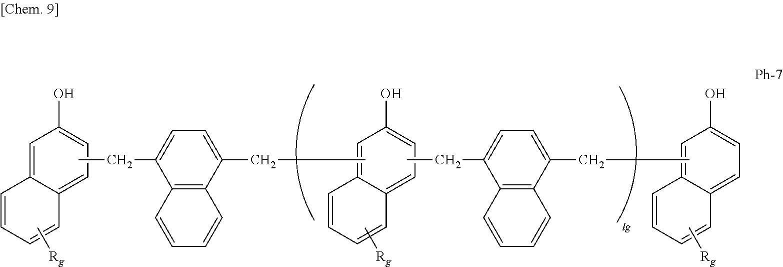

(In the formula, Rg represents a hydrogen atom or a hydrocarbon group having 1 to 6 carbon atoms and 1g represents the number of repeating units and is an integer in the range of 0 to 10);
a biphenol represented by structural formula (Ph-8) below:

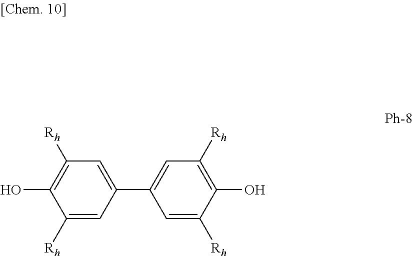

(In the formula, Rh each independently represent a hydrogen atom or an alkyl group having 1 to 4 carbon atoms);
a polyvalent naphthol represented by structural formula (Ph-9) below:

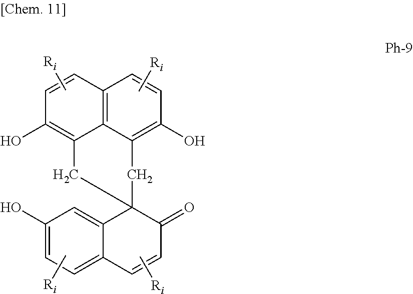

(In the formula, Ri each independently represent a hydrogen atom or an alkyl group having 1 to 4 carbon atoms); and a multifunctional phenol that contains, in the molecular structure, a structural portion represented by substructure formula (A3-j) below:
where the structural units, namely, a phenolic-hydroxyl-group-containing aromatic hydrocarbon group (Ph), an alkoxy-group-containing fused polycyclic aromatic hydrocarbon group (An), and a divalent hydrocarbon group (M) selected from a methylene group, an alkylidene group, and an aromatic hydrocarbon structure-containing methylene group (hereinafter this is simply referred to as “a methylene group or the like (M)”), are respectively represented by “Ph”, “An”, and “M”:

[Chem. 12]

-Ph-M-An- A3-j

Among these, those which have a resin structure in which a divalent organic group connects phenol nuclei and the aromatic nucleus that has a phenolic hydroxyl group is a benzene ring such as bisphenol, a novolac-type phenolic resin, and an aralkyl-type phenolic resin, are preferable since they are suitable for industrial production and have significant effects of improving the prepreg appearance and heat resistance during production of the prepreg.

Accordingly, in the present invention, particularly preferable is a phosphorus-atom-containing phenolic resin having a molecular structure represented by structural formula (1) below:

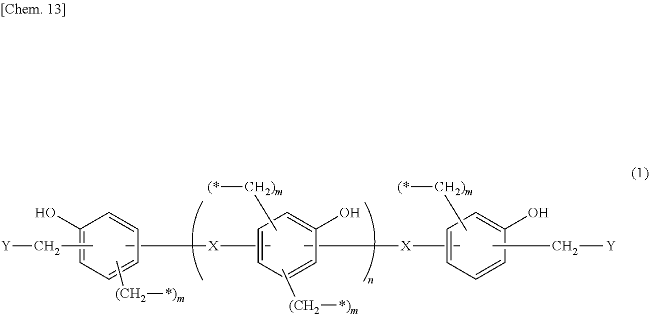

in which the site marked by is bonded to Y or forms a structure in which the site marked by is bonded, via an oxygen atom, to the site of another molecular structure represented by structural formula (1) or in which the site marked by is bonded to an aromatic nucleus of another molecular structure represented by structural formula (1), X represents a divalent organic connecting group or a single bond, Y represents a structural portion selected from the group consisting of structural formula (Y′1) below, structural formula (Y′2) below, and an alkoxy group having 1 to 8 carbon atoms:

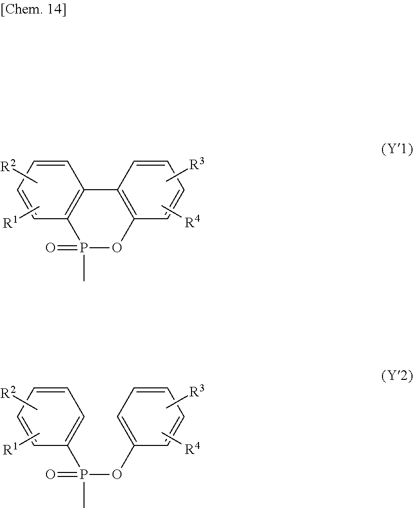

(In structural formulae (Y′1) and (Y′2), R¹ to R⁴ each independently represent a hydrogen atom or an alkyl group having 1 to 4 carbon atoms), m is 0 or 1, n represents the number of repeating units and is an integer of 0 to 100, and 5 to 20 mol % of Y are alkyl groups having 1 to 8 carbon atoms.

X may be any divalent organic group that connects the aromatic nuclei in the bisphenol, novolac-type phenolic resin, or aralkyl-type phenolic resin described above. X is preferably selected from the group consisting of methylene, 2,2-propylidene, phenylmethylene, and phenylenedimethylene since the phosphorus-atom-containing phenolic resin exhibits low viscosity and the prepreg has good appearance. In particular, X is preferably methylene or 2,2-propylidene.

The phosphorus-atom-containing phenolic resin described in detail above can be obtained by causing the aforementioned phenolic compound to react with formaldehyde in the presence of a basic catalyst to obtain a polycondensate containing a methylol group (step 1), then causing the polycondensate to react with an aliphatic monoalcohol having 1 to 8 carbon atoms to conduct etherification and obtain an alkoxymethyl-group-containing resin (α) (step 2), and causing the resin (α) to react with a phosphorus-atom-containing compound (β) represented by structural formula (β-1) or (β-2) below:

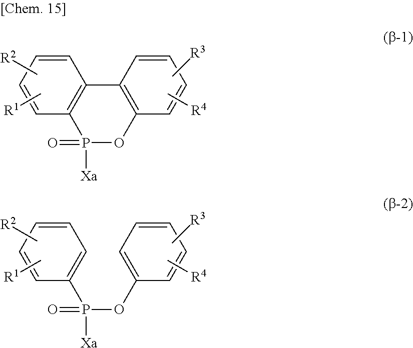

(In structural formula (β-1) or (β-2), Xa represents a hydrogen atom or a hydroxyl group, and R¹, R², R³, and R⁴ each independently represent a hydrogen group, an alkyl group having 1 to 5 carbon atoms, a chlorine atom, a bromine atom, a phenyl group, or an aralkyl group) while removing alcohol as generated (step 3).

Specific examples of the basic catalyst that can be used in step 1 include alkaline earth metal hydroxides, alkali metal carbonate salts, and alkali metal hydroxides. Alkali metal hydroxides such as sodium hydroxide and potassium hydroxide are preferable since they have good catalyst activity. The basic catalyst may be used in the form of an aqueous solution having a concentration of about 10 to 55% by mass or may be used in a solid form. The amount of the basic catalyst used is not particularly limited, and may be, for example, in the range of 0.5 to 5 equivalents and preferably 0.8 to 3 equivalents relative to the hydroxyl groups in the raw material phenolic compound.

For the formaldehyde used in step 1, a formalin aqueous solution, paraformaldehyde, or trioxane can be used as the formaldehyde source. In the present invention, a 35% formalin aqueous solution is preferably used since handling and control of reaction are easy.

The reaction ratio of the formaldehyde and the phenolic compound is preferably 4 to 40 mol and more preferably 5 to 10 mol of formaldehyde per mole of the phenolic compound.

The reaction in step 1 can usually be carried out in an aqueous solvent or a mixed solvent containing water and an organic solvent. In the case where an organic solvent is used, the amount of the organic solvent used is preferably in the range of about 1 to 5 times and more preferably about 2 to 3 times the amount of the raw material phenolic compound in terms of weight ratio.

Examples of the organic solvent include alcohols such as methanol, ethanol, n-propyl alcohol, n-butanol, ethylene glycol, ethylene glycol monomethyl ether, diethylene glycol, and carbitol, aromatic hydrocarbons such as toluene and xylene, and water-soluble aprotic polar solvents such as dimethyl sulfoxide, N-methylpyrrolidone, and dimethylformamide.

The reaction in step 1 can be carried out at a temperature in the range of 10 to 60° C. and more preferably in the range of 20 to 50° C.

Upon completion of the reaction, if needed, an acid is added to conduct neutralization and a methylol-group-containing polycondensate, which is a target product, can be obtained by purification and isolation through conventional methods. Examples of the acid that can be used in the neutralization treatment include organic acids such as formic acid, acetic acid, propionic acid, and oxalic acid, and inorganic acids such as sulfuric acid, phosphoric acid, phosphorous acid, hypophosphorous acid, and hydrochloric acid.

Step 2 is a step of causing the methylol-group-containing polycondensate obtained in step 1 to react with an aliphatic monoalcohol having 1 to 8 carbon atoms so as to conduct etherification and obtain an alkoxymethyl-group-containing resin (α).

Specific examples of the aliphatic monoalcohol having 1 to 8 carbon atoms include methanol, ethanol, n-propyl alcohol, n-butyl alcohol, t-butyl alcohol, n-octyl alcohol, s-octyl alcohol, t-octyl alcohol, and 2-ethylhexyl alcohol. Among these, n-alcohol is preferred since production of the resin (α) is simple and removal of the alcohol in the subsequent step is easy. In particular, an alcohol having 1 to 4 carbon atoms such as methanol, ethanol, isopropyl alcohol, butyl alcohol, or the like, is preferred.

The amount of the aliphatic monoalcohol having 1 to 8 carbon atoms used is preferably 200 to 3000 parts by mass and more preferably 500 to 1500 parts by mass relative to 100 parts by mass of the methylol-group-containing polycondensate described above. Note that the aliphatic monoalcohol having 1 to 8 carbon atoms serves as a reaction solvent as well as a raw material.

Step 2 may be conducted in the absence of a catalyst or in the presence of an acid catalyst. Preferable examples of the acid catalyst used in this step include concentrated sulfuric acid, hydrochloric acid, nitric acid, p-toluene sulfonic acid, methane sulfonic acid, trifluoromethane sulfonic acid, cation exchange resin (acid type), and oxalic acid. A more preferable example is an inorganic strong acid such as concentrated sulfuric acid. Usually, 0.1 to 100 parts by weight and preferably 0.5 to 30 parts by weight of the acid catalyst can be used relative to 100 parts by weight of the methylol-group-containing polycondensate.

The reaction temperature in step 2 is usually in the range of 15 to 80° C. and preferably in the range of 40 to 60° C.

Upon completion of the reaction, purification is conducted as needed and an alkoxymethyl-group-containing resin (α), which is a target product, can be isolated from the obtained reaction mixture by a conventional method.

When a phenol is used as the phenolic compound, specific examples of the alkoxymethyl-group-containing resin (α) include compounds represented by structural formulae (1-a-1) and (1-a-2) below:

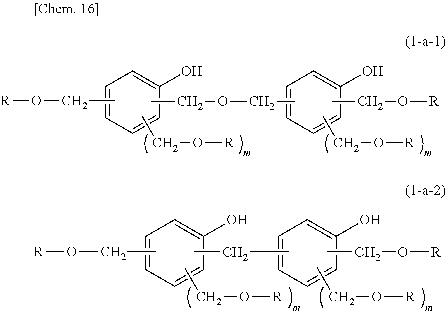

(In structural formulae (1-a-1) and (1-a-2), R represents an alkyl group having 1 to 8 carbon atoms and m represents an integer which is either 0 or 1.), polymers each having a repeating unit which is a structural portion represented by structural formula (1-a-3) or (1-a-4):

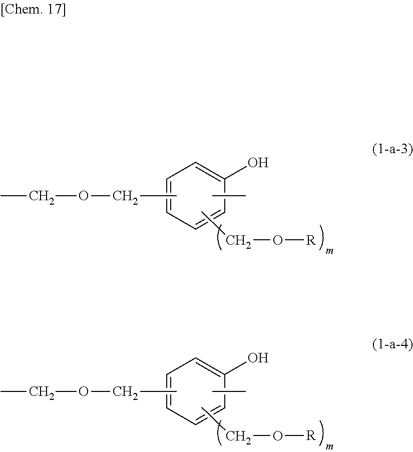

(In structural formulae (1-a-3) and (1-a-4), R represents an alkyl group having 1 to 8 carbon atoms and m is an integer of 1 to 2), a random or block polymer having repeating units represented by structural formula (1-a-3) and structural formula (1-a-4), and any mixture of these.

In the case where a bisphenol is used as the phenolic compound, examples of the bisphenol include compounds represented by structural formulae (1-b-1) to (1-b-3) below:

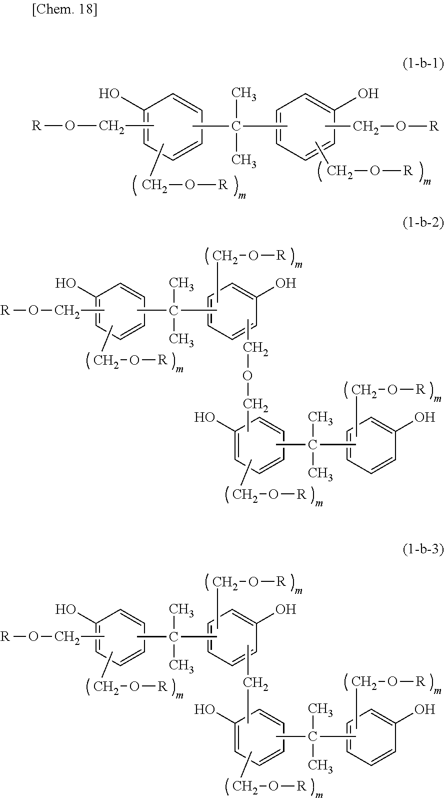

(In structural formulae (1-b-1) to (1-b-3), R represents an alkyl group having 1 to 8 carbon atoms and m is 0 or 1), a polymer having a repeating unit which is a structural portion represented by structural formula (1-b-4) or (1-b-5) below:

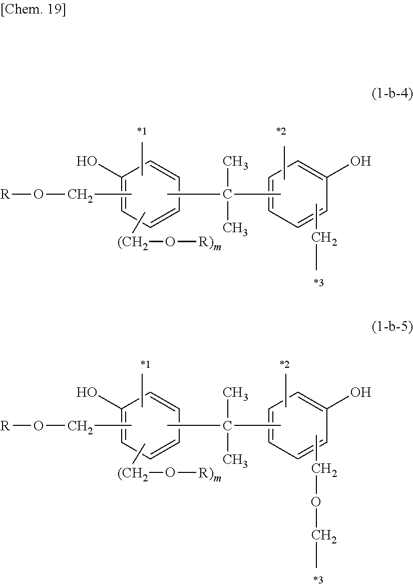

(In structural formulae (1-b-4) to (1-b-5), R represents an alkyl group having 1 to 8 carbon atoms and m is an integer which is 0 or 1),
a random or block polymer having repeating units represented by structural formula (1-b-4) and structural formula (1-b-5), and any mixture of these. The structural units represented by structural formula (1-b-4) and (1-b-5) may each be a divalent structural unit in which freely selected two of the bonding sites *1 to *3 serve as bonding portions or a trivalent structural unit in which all of the bonding sites *1 to *3 serve as bonding portions.

As described above, the alkoxymethyl-group-containing resin (α) is reacted with a phosphorus-atom-containing compound (β) represented by structural formula (β-1) or (β-2) below:

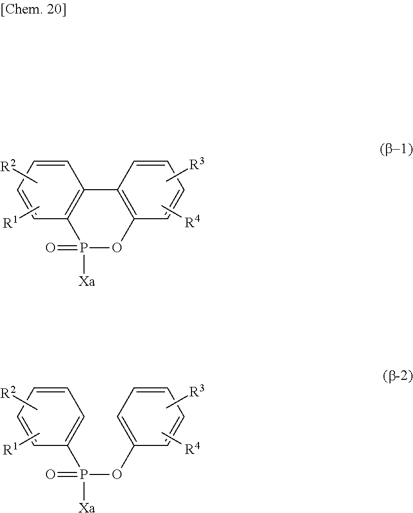

(In structural formula (β-1) or (β-2), Xa represents a hydrogen atom or a hydroxyl group and R¹, R², R³, and R⁴ each independently represent a hydrogen atom, an alkyl group having 1 to 5 carbon atoms, a chlorine atom, a bromine atom, a phenyl group, or an aralkyl group.)
so that the amount of R—O—CH₂— remaining is 5 to 20%.

In the present invention, Xa in structural formula (β-1) or (β-2) is preferably a hydrogen atom since the reactivity to the alkoxymethyl-group-containing resin (α) is notably enhanced. In particular, a compound represented by structural formula (β-1) is preferable since the cured product of the phosphorus-atom-containing phenolic resin exhibits excellent flame retardancy. Particularly preferred is 9,10-dihydro-9-oxa-10-phosphaphenanthrene-10-oxide which is a compound represented by structural formula (β-1) in which each of R1, R2, R3, and R4 represents a hydrogen atom and Xa represents a hydrogen atom because the cured product of the phosphorus-atom-containing phenolic resin finally obtained exhibits particularly favorable flame retardancy and heat resistance.

The reaction conditions for the alkoxymethyl-group-containing resin (α) and the phosphorus-atom-containing compound (β) are, for example, a temperature condition of 80 to 180° C. and the reaction can be conducted while removing the alcohol generated as the reaction proceeds. The reaction may be conducted in the presence of an acid catalyst such as oxalic acid, p-toluene sulfonic acid, sulfuric acid, or hydrochloric acid. From the viewpoints of high yield of the target product and good control of the side reaction, the reaction is preferably carried out in the absence of a catalyst. The organic solvent may be a non-ketone-based organic solvent such as an alcohol-based organic solvent or a hydrocarbon-based organic solvent.

After the reaction, dehydration and drying are conducted as needed to obtain a target substance.

The phosphorus-atom-containing phenolic resin obtained as such preferably has a hydroxyl equivalent in the range of 300 to 600 g/eq. since the cured product exhibits good heat resistance. The content of phosphorus atoms is preferably in the range of 5.0 to 12.0% by mass since the cured product exhibits good flame retardancy.

The phosphorus-atom-containing phenolic resin described in detail above is used as the phenolic resin (A) and as the curing agent for the epoxy resin (B) but can also be used as an additive-type flame retardant for thermoplastic resins such as polyamide, polycarbonate, polyester, polyphenylene sulfide, polystyrene, etc.

Various epoxy resins can be used as the epoxy resin (B) used in the curable resin composition of the present invention. Examples thereof include bisphenol-type epoxy resins such as bisphenol A-type epoxy resins and bisphenol F-type epoxy resins; biphenyl-type epoxy resins such as biphenyl-type epoxy resins and tetramethylbiphenyl-type epoxy resins; novolac-type epoxy resins such as phenol novolac-type epoxy resins, cresol novolac-type epoxy resins, bisphenol A novolac-type epoxy resins, an epoxidation product of a condensate between a phenol and an aromatic aldehyde having a phenolic hydroxyl group, and biphenyl novolac-type epoxy resins; triphenylmethane-type epoxy resins; tetraphenylethane-type epoxy resins; dicyclopentadiene-phenol addition reaction-type epoxy resins; phenol aralkyl-type epoxy resins; epoxy resins having naphthalene skeletons in molecular structures such as naphthol novolac-type epoxy resins, naphthol aralkyl-type epoxy resins, naphthol-phenol co-condensed novolac-type epoxy resins, naphthol-cresol co-condensed novolac-type epoxy resins, and diglycidyloxynaphthalene, 1,1-bis(2,7-diglycidyloxy-1-naphthyl)alkane; and phosphorus-atom-containing epoxy resins. These epoxy resins may be used alone or in combination as a mixture of two or more.

Examples of the phosphorus-atom-containing epoxy resin include an epoxidation product of 9,10-dihydro-9-oxa-10-phosphaphenanthrene-10-oxide (hereinafter, simply referred to as “HCA”), an epoxidation product of a phenolic resin obtained by reaction of HCA and a quinone, an epoxy resin obtained by modifying a phenol novolac-type epoxy resin with HCA, an epoxy resin obtained by modifying a cresol novolac-type epoxy resin with HCA, an epoxy resin obtained by modifying a bisphenol A-type epoxy resin with a phenolic resin obtained by a reaction of HCA and a quinone, and an epoxy resin obtained by modifying a bisphenol F-type epoxy resin with a phenolic resin obtained by the reaction of HCA and a quinone.

Among the epoxy resins (B) described above, an epoxy resin having a naphthalene skeleton and a novolac-type epoxy resin in a molecular structure is preferred from the viewpoint of heat resistance and a bisphenol-type epoxy resin and a novolac-type epoxy resin are preferred from the viewpoint that the composition exhibits a good glass-cloth penetrating property.

The curable resin composition according to the present invention may use another curing agent (A′) in addition to the phenolic resin (A) as the curing agent for the epoxy resin (B). Examples of the other curing agent (A′) include amine-based compounds, amide-based compounds, acid anhydride-based compounds, and a phenol-based compounds. Examples of the amine-based compounds include diaminodiphenylmethane, diethylenetriamine, triethylenetetramine, diaminodiphenylsulfone, isophoronediamine, imidazole, BF₃-amine complexes, and guanidine derivatives. Examples of the amide-based compounds include dicyanamide and a polyamide resin synthesized from a dimer of linoleic acid and ethylenediamine. Examples of the acid anhydride-based compound include phthalic anhydride, trimellitic anhydride, pyromellitic anhydride, maleic anhydride, tetrahydrophthalic anhydride, methyltetrahydrophthalic anhydride, nadic methyl anhydride, hexahydrophthalic anhydride, and methylhexahydrophthalic anhydride. Examples of the phenol-based compound include polyvalent phenolic compounds such as phenol novolac resins, cresol novolac resins, phenolic resins modified with aromatic hydrocarbon formaldehyde resins, dicyclopentadienephenol addition-type resins, phenol aralkyl resins (Xylok resin), naphthol aralkyl resins, trimethylol methane resins, tetraphenylolethane resins, naphthol novolac resins, naphthol-phenol co-condensed novolac resins, naphthol-cresol co-condensed novolac resins, biphenyl-modified phenolic resins (a polyvalent phenolic compound in which phenol nuclei are connected with a bismethylene group), biphenyl-modified naphthol resins (polyvalent naphthol compound in which phenol nuclei are connected with a bismethylene group), aminotriazine-modified phenolic resins (a compound having a phenol skeleton, a triazine ring, and a primary amino group in a molecular structure), and alkoxy-group-containing aromatic ring-modified novolac resins (a polyvalent phenolic compound in which phenol nuclei and an alkoxy-group-containing aromatic ring are connected with formaldehyde).

Among these, a compound that contains many aromatic skeletons in the molecular structure is preferred from the viewpoint of low thermal expansion. In particular, a phenol novolac resin, a cresol novolac resin, a phenolic resin modified with an aromatic hydrocarbon formaldehyde resin, a phenol aralkyl resin, a naphthol aralkyl resin, a naphthol novolac resin, a naphthol-phenol co-condensed novolac resin, a naphthol-cresol co-condensed novolac resin, a biphenyl-modified phenolic resin, a biphenyl-modified naphthol resin, an aminotriazine-modified phenolic resin, and an alkoxy-group-containing aromatic ring-modified novolac resin (a polyvalent phenolic compound in which phenol nuclei and an alkoxy-group-containing aromatic ring are connected with formaldehyde) are preferred since they have favorable low thermal expansion.

The aminotriazine-modified phenolic resin, namely, a compound having a phenol skeleton, a triazine ring, and a primary amino group in the molecular structure, preferably has a molecular structure obtained by a condensation reaction of a triazine compound, a phenol, and an aldehyde since the cured product exhibits good flame retardancy. In the present invention, the nitrogen atom content in the compound (A′-b) is preferably 10 to 25% by mass and more preferably 15 to 25% by mass since the cured product exhibits a significantly decreased linear expansion coefficient and good dimensional stability.

In the case where a triazine compound, a phenol, and an aldehyde are subjected to condensation reaction as described above, actually, a mixture of various compounds is obtained. Thus, the compound (A′-b) is preferably used as such a mixture (hereinafter this is simply referred to as “mixture (A′-b)”). In the present invention, the nitrogen atom content in the mixture (A′-b) is preferably in the range of 10 to 25% by mass and more preferably 15 to 25% by mass from the viewpoint of low linear expansion coefficient.

A phenol skeleton refers to a phenol structural portion derived from a phenol and a triazine skeleton refers to a triazine structural portion derived from a triazine compound.

The phenol used herein is not particularly limited. Examples thereof include phenol, alkyl phenols such as o-cresol, m-cresol, p-cresol, xylenol, ethylphenol, butylphenol, nonylphenol, and octyl phenol, polyvalent phenols such as bisphenol A, bisphenol F, bisphenol S, bisphenol AD, tetramethyl bisphenol A, resorcin, and catechol, naphthols such as monohydroxynaphthalene and dihydroxynaphthalene, and other phenyl phenols and amino phenols. These phenols can be used alone or in combination. A phenol is preferred since the final cured product exhibits excellent flame retardancy and the phenol has excellent reactivity to the amino-group-containing triazine compound.

The compound having a triazine ring is not particularly limited but is preferably a compound represented by the following structural formula or an isocyanuric acid:

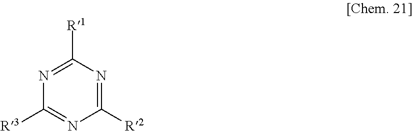

(In the formula, R′¹, R′², and R′³ each represent an amino group, an alkyl group, a phenyl group, a hydroxyl group, a hydroxyl alkyl group, an ether group, an ester group, an acid group, an unsaturated group, or a cyano group.)

Among the compounds represented by the structural formula above, an amino-group-containing triazine compound with two or three of R′¹, R′², and R′³ representing amino groups, such as guanamine derivatives, e.g., melamine, acetoguanamine, and benzoguanamine, are preferred for their high reactivity.

These compounds can be used alone or in combination of two or more.

The aldehyde is not particularly limited but is preferably formaldehyde from the viewpoint of handling ease. The formaldehyde is not particularly limited but representative examples of the supply source include formalin and paraformaldehyde.

The blend amounts of the epoxy resin (B) and the phenolic resin (A) in the curable resin composition of the present invention are not particularly limited. Preferably, 0.7 to 1.5 equivalents of active hydrogen is contained in the phenolic resin (A) relative to a total of one equivalent of epoxy groups in the epoxy resin (B) since the cured product obtained therefrom exhibits good properties.

If needed, a curing accelerator may also be used in the curable resin composition of the present invention. Various agents can be used as the curing accelerator. Examples thereof include phosphorus-based compounds, tertiary amines, imidazole, organic acid metal salts, Lewis acids, and amine complex salts. When used in a semiconductor sealing material usage, the curing accelerator is preferably a triphenylphosphine if a phosphorus-based compound is to be used or 2-ethyl-4-methylimidazole if an amine-based compound is to be used since the curability, heat resistance, electrical properties, anti-moisture reliability, etc., are enhanced.

The curable resin composition according to the invention described in detail above preferably contains an organic solvent (C) in addition to the components described above. Examples of the organic solvent (C) that can be used include methyl ethyl ketone, acetone, dimethylformamide, methyl isobutyl ketone, methoxypropanol, cyclohexanone, methyl cellosolve, ethyl diglycol acetate, and propylene glycol monomethyl ether acetate. The choice of the organic solvent and the appropriate amount of use can be appropriately made and adjusted depending on the usage. For example, for printed wiring board usages, a polar solvent having a boiling point of 160° C. or lower, such as methyl ethyl ketone, acetone, or 1-methoxy-2-propanol, is preferred and the polar solvent is preferably used in such an amount that the non-volatile content is 40 to 80% by mass. In contrast, for building-up adhesive film usages, the organic solvent (C) is preferably a ketone such as acetone, methyl ethyl ketone, or cyclohexanone, an acetic acid ester such as ethyl acetate, butyl acetate, cellosolve acetate, propylene glycol monomethyl ether acetate, or carbitol acetate, a carbitol such as cellosolve or butyl carbitol, an aromatic hydrocarbon such as toluene or xylene, dimethyl formamide, dimethyl acetamide, or N-methyl pyrrolidone and the organic solvent is preferably used in such an amount that the non-volatile content is 30 to 60% by mass.

In order for the thermosetting resin composition to exhibit flame retardancy, a non-halogen-based flame retardant substantially free of halogen atoms may be blended within the range that does not degrade the reliability in the field of, for example, printed wiring boards.

Examples of the non-halogen-based flame retardant include phosphorus-based flame retardants, nitrogen-based flame retardants, silicone-based flame retardants, inorganic flame retardants, and organic metal salt-based flame retardants. There is no limitation on the use of these flame retardants. These retardants can be used alone, two or more flame retardants of the same base can be used together, or flame retardants of different bases can be used in combination.

The phosphorus-based flame retardant may be inorganic or organic. Examples of the inorganic compounds include red phosphorus, ammonium phosphates such as monoammonium phosphate, diammonium phosphate, triammonium phosphate, and ammonium polyphosphate, and inorganic nitrogen-containing phosphorus compounds such as phosphoric amide.

The red phosphorus is preferably surface-treated to prevent hydrolysis and the like. Examples of the surface treatment include (i) a method of coating the surfaces with an inorganic compound such as magnesium hydroxide, aluminum hydroxide, zinc hydroxide, titanium hydroxide, bismuth oxide, bismuth hydroxide, bismuth nitrate, or any mixture of these, (ii) a method of coating the surfaces with a mixture of a thermosetting resin such as a phenolic resin and an inorganic compound such as magnesium hydroxide, aluminum hydroxide, zinc hydroxide, or titanium hydroxide, and (iii) a method of coating the surfaces with an inorganic compound such as magnesium hydroxide, aluminum hydroxide, zinc hydroxide, or titanium hydroxide, and then coating the inorganic compound with a thermosetting resin such as a phenolic resin to provide double coating.

Examples of the organic phosphorus-based compounds include commodity organophosphorus compounds such as phosphate ester compounds, phosphonic acid compounds, phosphinic acid compounds, phosphine oxide compounds, phosphorane compounds, and organic nitrogen-containing phosphorus compounds, and cyclic organophosphorus compounds and derivatives thereof obtained by reacting the cyclic organophosphorus compounds with compounds such as epoxy resins and phenolic resins, such as 9,10-dihydro-9-oxa-10-phosphaphenanthrene-10-oxide, 10-(2,5-dihydroxyphenyl)-10H-9-oxa-10-phosphaphenanthrene-10-oxide, and 10-(2,7-dihydroxynaphthyl)-10H-9-oxa-10-phosphaphenanthrene-10-oxide.

The amounts of these compounds blended are appropriately selected based on the type of the phosphorus-based flame retardant, other components of the curable resin composition, and the desired degree of flame retardancy. For example, in the case where red phosphorus is used as a non-halogen-based flame retardant in 100 parts by mass of the curable resin composition containing an epoxy resin, a curing agent, a non-halogen-based flame retardant, and all other components such as a filler, additives, etc., 0.1 to 2.0 parts by mass of red phosphorus is preferably blended. In the case where an organophosphorus compound is used, 0.1 to 10.0 parts by mass and more preferably 0.5 to 6.0 parts by mass of the organophosphorus compound is blended.

In the case where the phosphorus-based flame retardant is used, hydrotalcite, magnesium hydroxide, boride compounds, zirconium oxide, black dyes, calcium carbonate, zeolite, zinc molybdate, activated carbon, etc., may be used in combination with the phosphorus-based flame retardant.

Examples of the nitrogen-based flame retardant include a triazine compound, a cyanuric acid compounds, isocyanuric acid compounds, and phenothiazine. A triazine compound, a cyanuric acid compound, and isocyanuric acid compound are preferred.

Examples of the triazine compound include melamine, acetoguanamine, benzoguanamine, melon, melam, succinoguanamine, ethylene dimelamine, melamine polyphosphate, triguanamine, aminotriazine sulfate compounds such as guanylmelamine sulfate, melem sulfate, and melam sulfate, the aminotriazine-modified phenolic resin described above, and a product obtained by modifying the aminotriazine-modified phenolic resin with tung oil or isomerized linseed oil.

Specific examples of the cyanuric acid compound include cyanuric acid and melamine cyanurate.

The amount of the nitrogen-based flame retardant blended is appropriately selected based on the type of the nitrogen-based flame retardant, other components of the curable resin composition, and the desired degree of the flame retardancy. For example, the amount of the nitrogen-based flame retardant is preferably 0.05 to 10 parts by mass and more preferably 0.1 to 5 parts by mass in 100 parts by mass of the curable resin composition containing an epoxy resin, a curing agent, a non-halogen-based flame retardant, and all other components such as a filler and additives.

In the case where the nitrogen-based flame retardant is used, a metal hydroxide, a molybdenum compound, etc., may be used in combination.

The silicone-based flame retardant may be any organic compound that contains a silicon atom. Examples thereof include silicone oil, silicone rubber, and silicone resins.

The amount of the silicone-based flame retardant blended is appropriately selected based on the type of the silicone-based flame retardant, other components of the curable resin composition, and the desired degree of flame retardancy. For example, 0.05 to 20 parts by mass of the silicone-based flame retardant is preferably contained in 100 parts by mass of the curable resin composition that contains an epoxy resin, a curing agent, a non-halogen-based flame retardant, and all other components such as a filler and additives. The silicone-based flame retardant may be used in combination with a molybdenum compound, alumina, etc.

Examples of the inorganic flame retardant include metal hydroxides, metal oxides, metal carbonate salt compounds, metal powder, boron compounds, and low-melting-point glass.

Specific examples of the metal hydroxide include aluminum hydroxide, magnesium hydroxide, dolomite, hydrotalcite, calcium hydroxide, barium hydroxide, and zirconium hydroxide.

Specific examples of the metal oxides include zinc molybdate, molybdenum trioxide, zinc stannate, tin oxide, aluminum oxide, iron oxide, titanium oxide, manganese oxide, zirconium oxide, zinc oxide, molybdenum oxide, cobalt oxide, bismuth oxide, chromium oxide, nickel oxide, copper oxide, and tungsten oxide.

Specific examples of the metal carbonate salt compounds include zinc carbonate, magnesium carbonate, calcium carbonate, barium carbonate, basic magnesium carbonate, aluminum carbonate, iron carbonate, cobalt carbonate, and titanium carbonate.

Specific examples of the metal powder include aluminum, iron, titanium, manganese, zinc, molybdenum, cobalt, bismuth, chromium, nickel, copper, tungsten, and tin.

Specific examples of the boron compounds include zinc borate, zinc metaborate, barium metaborate, boric acid, and borax.

Specific examples of the low-melting-point glass include glassy compounds such as CEEPREE (Bokusui Brown Co., Ltd.), hydrated glass SiO₂—MgO—H₂O, and compounds based on PbO—B₂O₃, ZnO—P₂O₅—MgO, P₂O₅—B₂O₃—PbO—MgO, P—Sn—O—F, PbO—V₂O₅—TeO₂, Al₂O₃—H₂O, and lead borosilicate.

The amount of the inorganic flame retardant blended is appropriately selected based on the type of the inorganic flame retardant, other components of the curable resin composition, and the desired degree of flame retardancy. For example, the amount of the inorganic flame retardant is preferably 0.05 to 20 parts by mass and more preferably 0.5 to 15 parts by mass in 100 parts by mass of the curable resin composition that contains an epoxy resin, a curing agent, a non-halogen-based flame retardant, and all other components such as a filler and additives.

Examples of the organic metal salt-based flame retardant include ferrocene, acetylacetonate metal complexes, organic metal carbonyl compounds, organic cobalt salt compounds, organic sulfonic acid metal salts, and a compound in which a metal atom and an aromatic compound or a heterocyclic compound are ion-bonded or coordinate-bonded to each other.

The amount of the organic metal salt flame retardant blended is appropriately selected based on the type of the organic metal salt-based flame retardant, other components of the curable resin composition, and the desired degree of flame retardancy. For example, 0.005 to 10 parts by mass of the organic metal salt-based flame retardant is blended in 100 parts by mass of the curable resin composition that contains an epoxy resin, a curable agent, a non-halogen-based flame retardant, and all other components such as a filler and additives.

The curable resin composition of the present invention may contain an inorganic filler if needed. Examples of the inorganic filler include fused silica, crystalline silica, alumina, silicon nitride, and aluminum hydroxide. In the case where the amount of the inorganic filler is to be particularly large, fused silica is preferably used. Fused silica may be crushed or spherical. In order to increase the amount of the fused silica blended and suppress the increase in melt density of the forming materials, spherical fused silica is preferably mainly used. In order to increase the amount of the spherical silica blended, the particle size distribution of spherical silica is preferably appropriately adjusted. The filling ratio is preferably high considering flame retardancy and is preferably 20% by mass or more relative to the entire amount of the curable resin composition. When the composition is to be used for conductive paste usage etc., a conductive filler such as silver powder or copper powder can be used.

The curable resin composition of the present invention can contain various blend compounds such as a silane coupling agent, a mold releasing agent, a pigment, and an emulsifier, as needed.

The curable resin composition of the present invention is obtained by homogeneously mixing the components described above. The curable resin composition of the present invention containing an epoxy resin, a curing agent, and, if needed, a curing accelerator can be easily formed into a cured product by the same method as those known in the related art. Examples of the cured product include molded cured products such as a laminate, a cast molded product, an adhesive layer, a coating film, and a film.

Examples of the usage of the curable resin composition of the present invention include printed wiring board materials, resin compositions for flexible wiring boards, interlayer insulating materials for build-up substrates, semiconductor sealing materials, conductive paste, adhesive films for building-up, a resin mold casting material, and an adhesive. Regarding the use in insulating materials for printed wiring boards and electronic circuit substrates and the adhesive film for building-up among these usages, the composition can be used as an insulating material for a substrate having built-in electronic parts, which is a substrate in which passive parts such as capacitors and active parts such as IC chips are embedded. In particular, the composition is preferably used as a resin composition for flexible wiring boards and interlayer insulating materials for build-up substrates due to properties such as high flame retardancy, high heat resistance, low thermal expansion, and good prepreg appearance.

An example of a method for manufacturing a printed wiring board from the curable resin composition of the present invention is a method that includes preparing a resin composition by varnishing a varnish-type curable resin composition containing the organic solvent (D) by further adding the organic solvent (D), impregnating a reinforcing substrate with the resin composition, superimposing a copper foil on the reinforcing substrate, and performing thermal press bonding. The reinforcing substrate that can be used here may be paper, glass cloth, glass unwoven cloth, aramid paper, aramid cloth, a glass mat, glass roving cloth, or the like. The method can be described in detail as follows. First, a varnish-type curable resin composition is heated to a heating temperature suitable for the type of the solvent used, preferably a temperature of 50 to 170° C., to obtain a prepreg, which is a cured product. The mass ratio of the resin composition to the reinforcing substrate is not particularly limited but the resin content in the prepreg is usually preferably adjusted to 20 to 60% by mass. Then the prepreg obtained as above is laminated by a conventional method, a copper foil is superimposed thereon, and thermal press-bonding is performed at a pressure 1 to 10 MPa at 170 to 250° C. for 10 minutes to 3 hours. As a result, the intended printed wiring board can be obtained.

### EXAMPLES

The present invention will now be described in detail through Examples and Comparative Examples. The measurement of melt viscosity at 180° C., GPC measurement, and NMR MS analysis were conducted under the following conditions:

1) Melt viscosity at 180° C.: measured in accordance with ASTM D4287
2) Softening point measurement method: JIS K7234
3) GPC: Measurement conditions were as follows:
Measurement instrument: “HLC-8220 GPC” produced by Tosoh Corporation
Columns: Guard column “HXL-L” produced by Tosoh Corporation
+“TSK-GEL G2000HXL” produced by Tosoh Corporation
+“TSK-GEL G2000HXL” produced by Tosoh Corporation
+“TSK-GEL G3000HXL” produced by Tosoh Corporation
+“TSK-GEL G4000HXL” produced by Tosoh Corporation
   Detector: RI (differential refractometer)
   Data processing: “GPC-8020 model II, version 4.10” produced by Tosoh Corporation

### Measurement Conditions:

Column temperature: 40° C.
Eluent: tetrahydrofuran
Flow rate: 1.0 ml/min
   Standard: The following monodisperse polystyrenes with known molecular weights were used in accordance with the measurement manual of “GPC-8020 model II, version 4.10”:

(Polystyrenes Used)
“A-500” produced by Tosoh Corporation
“A-1000” produced by Tosoh Corporation
“A-2500” produced by Tosoh Corporation
“A-5000” produced by Tosoh Corporation
“F-1” produced by Tosoh Corporation
“F-2” produced by Tosoh Corporation
“F-4” produced by Tosoh Corporation
“F-10” produced by Tosoh Corporation
“F-20” produced by Tosoh Corporation
“F-40” produced by Tosoh Corporation
“F-80” produced by Tosoh Corporation
“F-128” produced by Tosoh Corporation
   Sample: a 1.0% by mass tetrahydrofuran solution on a resin solid basis was filtered with a microfilter (50 μl). 5)¹³C-NMR: NMR GSX270 produced by JEOL Ltd.

### Synthetic Example 1

### Step 1: Synthesis of Methylol-Group-Containing Polycondensate

Into a flask equipped with a thermometer, a cooling tube, a distillation tube, and a stirrer, 100 parts by mass (0.5 mol) of bisphenol F (DIC-BPF) and 700 parts by mass (1.4 mol) of a 16% sodium hydroxide aqueous solution were fed and the resulting mixture was stirred. To the resulting mixture, 142.9 parts by mass (3.5 mol) of a 42% formaldehyde was added dropwise over 1 hour while the mixture was kept at 30 to 40° C. Upon completion of the dropwise addition, the mixture was stirred 18 hours and then a mixed solution of methyl ethyl ketone and methyl isobutyl ketone was added thereto and the resulting mixture was neutralized with diluted sulfuric acid.

The water layer was separated and the obtained organic layer was washed with distilled water twice. Then the solvent was distilled away from the organic layer at a reduced pressure. As a result, 125 parts of a solid resin (A-1) was obtained.

### Step 2: Methyl Etherification

Into a flask equipped with a thermometer, a cooling tube, a distillation tube, and a stirrer, 2000 parts by mass of methanol and 33 parts by mass of sulfuric acid were fed and the resulting mixture was stirred to form a homogeneous solution. To the solution, 107 parts of a resin (A) was added at 60° C. over 1 hour. Upon completion of feeding, stirring was conducted for 20 hours to carry out the reaction.

Then the mixture was neutralized with a sodium hydroxide aqueous solution and the solvent was distilled away at a reduced pressure. Methyl isobutyl ketone was added thereto to dissolve and the resulting mixture was washed with distilled water. Then water was removed by decanting, the mixture was filtered, and the solvent was distilled away at a reduced pressure. As a result, 115 parts by mass of a solid resin (B−1) was obtained.

### Step 3: Addition of DOPO

Into a flask equipped with a thermometer, a cooling tube, a distillation tube, and a stirrer, 94 parts by mass of the solid resin (B−1) obtained in Synthetic Example 2, 194.4 parts by mass of 9,10-dihydro-9-oxa-10-phosphaphenanthrene-10-oxide (hereinafter referred to as DOPO), and 126 parts by mass of 1-methoxy-2-propanol were added. The resulting mixture was stirred to prepare a homogeneous solution. The mixture was heated at 170° C. for 1 hour and 190° C. for 1 hour at a reduced pressure under stirring to conduct reaction. As a result, 245 parts by mass of a phosphorus-atom-containing phenolic resin (C−1) was obtained. The theoretical phosphorus content in the obtained resin was 10.7% and the hydroxyl equivalent was 519 g/eq. The existence ratio [(ii)/(i)] of methoxymethyl groups (ii) to the structural portions (i) represented by formula (i) derived from ¹³C-NMR was 0.10 (the existence ratio relative to the total number of (i) and (ii) was 9.1%):

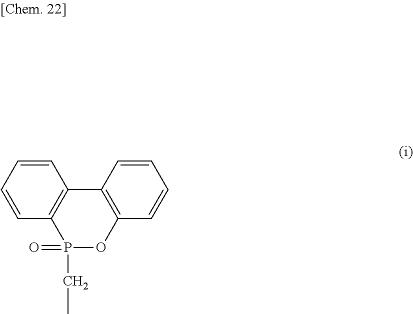 [SMILES: CCP1(=O)Oc2ccccc2-c2ccccc21]

### Synthetic Example 2

Two-hundred fifty parts by mass of a phosphorus-atom-containing phenolic resin (C-2) was obtained as in Synthetic Example 1 except that 203 parts by mass of DOPO was used in step 3 of Synthetic Example 1. The theoretical phosphorus content of the obtained resin was 10.9% and the hydroxyl equivalent was 534 g/eq. The existence ratio [(ii)/(i)] of methoxymethyl groups (ii) to the structural portions (i) represented by formula (i) derived from ¹³C-NMR was 0.06 (the existence ratio relative to the total number of (i) and (ii) was 5.7%).

### Synthetic Example 3

Two-hundred thirty-eight parts by mass of a phosphorus-atom-containing phenolic resin (C-3) was obtained as in Synthetic Example 1 except that 177.1 parts by mass of DOPO was used in step 3 of Synthetic Example 1. The theoretical phosphorus content of the obtained resin was 10.3% and the hydroxyl equivalent was 490 g/eq. The existence ratio [(ii)/(i)] of methoxymethyl groups (ii) to the structural portions (i) represented by formula (i) derived from ¹³C-NMR was 0.18 (the existence ratio relative to the total number of (i) and (ii) was 15.3%).

### Synthetic Example 4

Two-hundred fifteen parts by mass of a phosphorus-atom-containing phenolic resin (C-4) was obtained as in Synthetic Example 1 except that 151 parts by mass of DOPO was used in step 3 of Synthetic Example 1. The theoretical phosphorus content of the obtained resin was 9.7% and the hydroxyl equivalent was 445 g/eq. The existence ratio [(ii)/(i)] of methoxymethyl groups (ii) to the structural portions (i) represented by formula (i) derived from ¹³C-NMR was 0.30 (the existence ratio relative to the total number of (i) and (ii) was 23.1%).

### Synthetic Example 5

One hundred seventy parts by mass of a phosphorus-atom-containing phenolic resin (C-5) was obtained as in Synthetic Example 1 except that 216 parts by mass of DOPO was used in step 3 of Synthetic Example 1. The theoretical phosphorus content of the obtained resin was 11.1% and the hydroxyl equivalent was 556 g/eq. The existence ratio [(ii)/(i)] of methoxymethyl groups (ii) to the structural portions (i) represented by formula (i) derived from ¹³C-NMR was 0.00.

### Examples 1 to 3 and Comparative Examples 1 and 2

### Preparation of Curable Resin Compositions and Physical Property Evaluation

Curable resin compositions were prepared according to the formulations indicated in Table 2 and test pieces were prepared by the following method. Evaluations were conducted and the results are indicated in Table 2.

### [Laminate Preparation Conditions]

Glass cloth substrate: 100 μm, glass cloth “2116’ for printed wiring board produced by Nitto Boseki Co., Ltd.

Number of plies: 6

Copper foil: 18 μm, TCR foil produced by Nippon Mining & Metals Co., Ltd.
Conditions of prepreg formation: 160° C., 2 minutes
Curing conditions: 200° C., 2.9 MPa, and 2.0 hours
Thickness after forming: 0.8 mm, resin content: 40%

### [Evaluation of Appearance of Prepreg]

A glass cloth substrate cut to a size of 50 cm×50 cm was impregnated with the curable resin composition according to [Laminate preparation conditions] described above and the appearance of the prepreg after drying was evaluated:
A: No thinned parts were observed
F: Thinned parts were observed

### [Heat Resistance Test]

Glass transition temperature: Test pieces were measured by TMA method. Temperature elevation rate: 3° C./min

Solder heat resistance test: After PCT treatment (121° C., 2 atm), the test piece was immersed in a solder bath at 288° C. for 30 seconds.

Evaluation
A: No bulging occurred
F: Bulging occurred

T288 test: The test method was as described in IPC TM650.

[Flame test] The test method was as described in UL-94 vertical test.

TABLE 1

| | | | | | Comparative | |
|---|---|---|---|---|---|---|
| | | Examples | | | Examples | |
| | | 1 | 2 | 3 | 1 | 2 |
| Epoxy resin | N-770 | 54.3 | 54.4 | 54.1 | 53.7 | 54.5 |
| Curing agent | C-1 | 18.7 | | | | |
| | C-2 | | 18.3 | | | |
| | C-3 | | | 19.4 | | |
| | C-4 | | | | 20.6 | |
| | C-5 | | | | | 18 |
| | TD-2090 | 27 | 27.3 | 26.5 | 25.6 | 27.5 |
| Catalyst | 2E4MZ/phr | 0.05 | 0.05 | 0.05 | 0.05 | 0.05 |
| Solvent | Methyl ethyl ketone | 59.6 | 72.5 | 72.4 | 72.4 | 72.4 |
| | 1-Methoxy-2-propanol | 12.8 | 12.8 | 12.8 | 12.8 | 12.8 |
| P content in composition/% | | 2 | 2 | 2 | 2 | 2 |
| Appearance of prepreg | | A | A | A | A | F |
| Heat | Glass transition temperature | 176 | 174 | 172 | 165 | 168 |
| resistance | (TMA) ° C. | | | | | |
| | Solder heat resistance test | A | A | A | F | A |
| | T288 | >60 | >60 | >60 | 50 | >60 |
| Flame test | Flame test class | V-0 | V-0 | V-0 | V-1 | V-1 |
| | *1 | 30 | 28 | 31 | 55 | 25 |
| | *2 | 6 | 5 | 6 | 10 | 5 |

Legends in Table 1 are as follows:
“N-770”: phenol novolac-type epoxy resin (“N-770” produced by DIC Corporation, epoxy equivalent: 185 g/eq.)
“C-1”: phenolic resin (A-1) obtained Example 1
“C-2”: phenolic resin (A-2) obtained Example 2
“C-3”: phenolic resin (A-3) obtained Example 3
“C-4”: phenolic resin (A-4) obtained Example 4
“C-5”: phenolic resin (A-5) obtained Example 5
“TD-2090”: phenol novolac resin (“TD-2090” produced by DIC Corporation, hydroxyl equivalent: 105 g/eq.)
“FX-289BER75”: phosphorus-modified epoxy resin (“FX-289BER75” produced by Tohto Kasei Co., Ltd., an epoxy resin obtained by causing a cresol novolac-type epoxy resin to react with 9,10-dihydro-9-oxa-10-phosphaphenanthrene-10-oxide, epoxy equivalent: 330 g/eq., P content: 3.0% by mass)

1. A curable resin composition comprising a phenolic resin (A) and an epoxy resin (B) as essential components, wherein the phenolic resin (A) is a phosphorus-atom-containing phenolic resin that has phosphorus-atom-containing structural portions (i) represented by structural formula (Y1) or (Y2) below and alkoxymethyl groups (ii) in an aromatic nucleus of a phenolic compound: 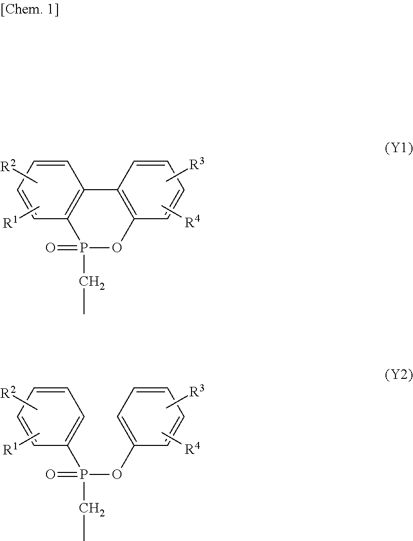
(In structural formulae (Y1) and (Y2), R¹ to R⁴ each independently represent a hydrogen atom or an alkyl group having 1 to 4 carbon atoms),
and a ratio of the number of the alkoxymethyl groups (ii) relative to the total number of the phosphorus-atom-containing structural portions (i) and the alkoxymethyl groups (ii) is 5 to 20%.

2. The curable resin composition according to claim 1, wherein the phenolic resin (A) has a molecular structure represented by structural formula (1) below: 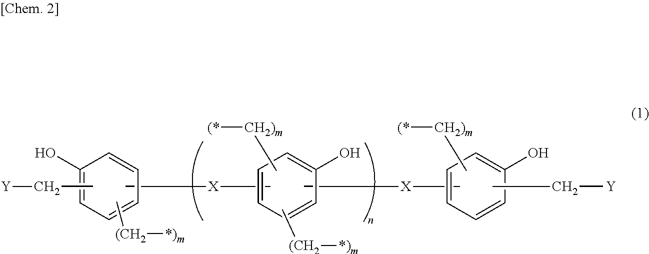
where the site marked by is bonded to Y or forms a structure in which the site marked by is bonded, via an oxygen atom, to the site of another molecular structure represented by structural formula (1) or in which the site marked by is bonded to an aromatic nucleus of another molecular structure represented by structural formula (1), X represents a divalent organic connecting group or a single bond, Y represents a structural portion selected from the group consisting of structural formula (Y′1) below, structural formula (Y′2) below, and an alkoxy group having 1 to 8 carbon atoms: 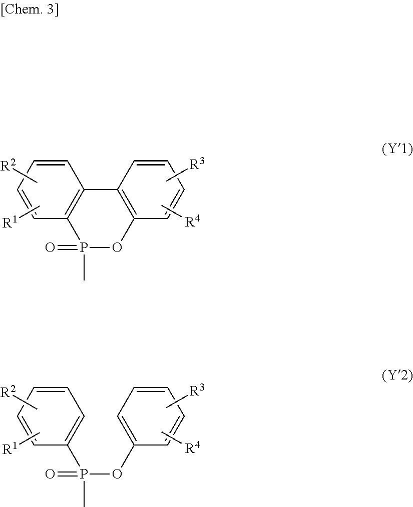
(In structural formulae (Y′1) and (Y′2), R¹ to R⁴ each independently represent a hydrogen atom or an alkyl group having 1 to 4 carbon atoms), m is 0 or 1, n represents the number of repeating units and is an integer of 0 to 100, and 5 to 20 mol % of Y are alkyl groups having 1 to 8 carbon atoms.

3. The curable resin composition according to claim 2, wherein, in the phosphorus-atom-containing phenolic resin, the structural portion represented by X in structural formula (1) is selected from the group consisting of methylene, 2,2-propylidene, phenylmethylene, and —CH₂—O—CH₂—.

4. The curable resin composition according to claim 1, wherein the phosphorus-atom-containing phenolic resin has a phosphorus atom content in the range of 5.0 to 12.0% by mass.

5. The curable resin composition according to claim 1, wherein the phenolic resin (A) and the epoxy resin (B) are blended at a ratio such that 0.7 to 1.5 equivalents of active hydrogen is contained in the phenolic resin (A) relative to a total of 1 equivalent of epoxy groups in the epoxy resin (B).

6. The curable resin composition according to claim 1, wherein a curing accelerator (C) is further blended in addition to the phenolic resin (A) and the epoxy resin (B).

7. The curable resin composition according to claim 1, wherein an organic solvent (D) is further contained in addition to component (A) to component (C).

8. A cured product obtained by curing the curable resin composition according to claim 1.

9. A resin composition for a printed wiring board, comprising the composition according to claim 7.

10. A printed wiring board obtained by impregnating a glass substrate with the composition according to claim 7 and then curing the composition.
